(19) United States
(12) Patent Application Publication
(10) Pub. No.: US 2025/0308931 A1
(43) Pub. Date: Oct. 2, 2025

(54) METHOD FOR REMOVING METAL-CONTAINING MATERIALS IN SMALL PITCH STRUCTURES

(71) Applicant: Tokyo Electron Limited, Tokyo (JP)

(72) Inventors: Yen-Tien Lu, Albany, NY (US); Kai-Hung Yu, Albany, NY (US)

(21) Appl. No.: 18/622,318

(22) Filed: Mar. 29, 2024

(51) Int. Cl. H01L 21/3213; H01L 21/768

(52) U.S. Cl. CPC H01L 21/32136; H01L 21/76883

(57) ABSTRACT

Undesired metal-containing material is removed from semiconductor substrates during fabrication of features in semiconductor devices in a method where at least a portion of the metal-containing material is removed from the semiconductor substrate by directing a gas cluster ion beam at the material at an irradiation angle α between the gas cluster ion beam and the major surface plane of from 5° to 85°. Various techniques of directing a gas cluster ion beam at the semiconductor substrate are described.

### FIELD

The present invention relates to removing metal-containing materials in small pitch structures, such as integrated circuit structures.

### BACKGROUND

In the semiconductor industry, increasing circuit density drives progress toward smaller and smaller dimensions and larger numbers of transistors placed in an individual device. Metal features in microelectronic devices include contacts and interconnects (i.e., wiring). Metal features in semiconductor devices can be formed by strategies such as damascene techniques and/or metal patterning techniques. In damascene techniques, trenches and vias are formed in a dielectric material, such as by etching, and then the trenches and vias are filled with metal, such as copper or other metal. Patterning techniques involve patterning metal films to form patterned metal features, typically by etching. In contrast to other dielectric materials, metal materials are more challenging to etch; hence, damascene strategies are often used to form metal interconnects. Damascene techniques include dual damascene, single damascene, and semi-damascene strategies. The “single” damascene process involves creating and filling the trenches (or vias) first and then proceeding to fill the trenches (or vias). Then, the etching and filling is repeated for the vias (or trenches). A “Dual” damascene process forms the trenches and vias at the same time and then fills both the trench and vias at the same time.

Gas cluster ion beam (“GCIB”) processes are disclosed in U.S. Pat. No. 11,450,506 that may be used to edit features within a patterned layer to provide feature sizes smaller than the resolution limit of the photolithography system used to form the initial pattern. Additionally, this patent notes that random variations in critical dimensions in a pattern result from surface roughness of sidewalls along the edges of features, such as lines, trenches, pillars, and holes within a patterned layer, and states that GCIB processes can enhance a patterned layer by smoothing the surfaces of features by trimming random protrusions from exposed surfaces using a gas cluster ion beam. Additionally, this patent states that GCIB trim etch process may also be applied to descum a patterned layer. The use of a GCIB to smooth a solid surface of substrate of e.g. a semiconductor is described in US Patent Application Publication Number 2014/0299465. In this disclosure, the angle formed between the solid surface and the gas cluster ion beam is chosen to be between 1° and an angle less than 30°.

A method for removing and/or redistributing material in the trenches and/or vias of integrated circuit interconnect structures by a gas cluster ion beam (GCIB) is described in U.S. Pat. No. 7,115,511 to improve the fabrication process and quality of metal interconnects in an integrated circuit. This patent expressly notes that “The etching/sputtering of the barrier material and/or copper seed material present on the interconnect trench or via sidewall is greatly minimized by the use of a gas cluster ion beam applied at approximately normal incidence to the surface of the integrated circuit (which is approximately parallel to the axis of the cylindrical interconnect via, or in the case of a trench-like via, approximately parallel to the median plane of the trench)” at column 7, lines 12-19.

### SUMMARY

As semiconductor device feature size continues to scale to smaller sizes, it is becoming an increasing challenge to reduce the device contact resistance, especially for devices having very small features using the conventional dual or single damascene flow strategies. Some aspects of next generation metallization are using semi damascene or subtractive metal etch flow. In a next generation technique, alternative interconnect metals, such as Ru, W, Mo, and Nb and damascene techniques are used to form some metal features to replace Cu. These interconnect metals, which have better electric properties and/or advantages of process fabrication compared to Cu, are deposited and then etched to form patterned metal features. In short, semi-damascene strategies form some metal features using patterning, and other metal features are formed using damascene techniques.

The development of the dual damascene process allowed the industry to develop devices with high aspect ratio features as well as to develop devices with Ru, rather than Cu, as the interconnect metal because Ru has low resistivity in a small scale. Ru does not need a barrier because it does not raise a concern of diffusion to surrounding inter-layer dielectrics (ILDs). However, interconnect metals such as Ru or other metal-containing materials may need prior application of a metal-containing material as a liner to improve the adhesion onto ILDs, or as a seed material to facilitate coating of the interconnect metal. The thus applied metal-containing material can for example be Ru, TiN, Ta, TaN, Nb, NbN and W, and combinations thereof. The metal-containing material may be deposited by atomic layer deposition (ALD) or other methods.

For this reason, a metal-containing material might be used as a liner with Ru, while at that same time maintaining high electrical conductivity for good electronic contact in the circuit. In an embodiment, the metal-containing material is desirably deposited in such a way as to form a continuous layer on the sidewalls of the trenches and vias.

In an embodiment, semiconductor substrates having a plurality adjacent, very small recesses bounded by thin semiconductor walls may tend to bend, collapse or fill unevenly. To counter these problems, one or more initial layers of metal-containing materials may be deposited to provide initial reinforcement of the thin semiconductor walls that prevents bend or collapse of the walls of the features or uneven filling of the recesses of the features. The metal-containing materials deposited in this fashion may be selected from the interconnect material of the ultimate feature, or may be a different metal-containing material as described herein.

Depositing these metal-containing materials on semiconductor substrates having features (e.g., vias and trenches) that are very small and/or have high aspect ratios often result in uneven thicknesses and structural problems with the small pitch structures. In particular, it has been found that depositing metal-containing materials on a semiconductor substrate comprising a major surface plane and having a recess extending into a semiconductor substrate having undesired metal-containing material on the major surface plane and/or in the recess, wherein at least one recess has a recess width in the narrowest dimension of not more than 50 nm.

Moreover, as the dimensions of microelectronic circuitry are reduced and as the sheer number of circuitry elements fabricated in a given region is increased, significant challenges arise in processing of such features. In particular, chip designs comprising a number of adjacent, very small features having high aspect ratios may be deformed during fabrication by, for example, line bending and pattern collapse.

It has been found that directing a gas cluster ion beam at the major surface plane of a substrate at an irradiation angle α between the gas cluster ion beam and the major surface plane of from 5° to 85° advantageously directs the gas cluster ion beam to locations of the substrate where problematic metal-containing material must be removed, while at the same time avoiding impingement of the gas cluster ion beam at locations of the substrate where removal of metal-containing material is disadvantageous. This selective removal of metal-containing material is carried out without the need to mask or introduce other protective steps in the fabrication process.

### BRIEF DESCRIPTION OF THE DRAWINGS

The accompanying drawings, which are incorporated in and constitute a part of this application, illustrate several aspects of the invention and together with a description of the embodiments explain the principles of the invention. A brief description of the drawings is as follows:

FIG. 1 is a schematic graphical illustration of a view of a prior art method of processing a recess extending into a semiconductor substrate comprising overhanging metal-containing material.

FIG. 2 is a schematic graphical illustration of a view of a method as described herein of processing a recess extending into a semiconductor substrate comprising overhanging metal-containing material.

FIG. 3 is a schematic graphical illustration of a view of a prior art method of processing a semiconductor substrate comprising a number of adjacent, very small features having high aspect ratios.

FIG. 4 is a schematic graphical illustration of a view of a method as described herein of processing a semiconductor substrate comprising a number of adjacent, very small features having high aspect ratios.

FIG. 5 is a schematic graphical illustration of a view of a prior art method of processing a recess extending into a semiconductor substrate comprising a metal-containing material by conventional dry etch or thermal etch techniques.

FIG. 6 is a schematic graphical illustration of a view of a method as described herein of processing a recess extending into a semiconductor substrate comprising a metal-containing material.

FIG. 7 is a schematic graphical illustration of a view of a prior art method of processing a recess extending into a semiconductor substrate comprising a metal-containing material having metal nuclei by conventional dry etch or thermal etch techniques.

FIG. 8 is a schematic graphical illustration of a view of a method as described herein of processing a recess extending into a semiconductor substrate comprising a metal-containing material having metal nuclei.

FIG. 9 is a schematic graphical illustration of a GCIB processing apparatus for directing the gas cluster ion beam onto the major surface plane of a substrate at the desired angle.

FIG. 10 is a schematic graphical illustration of a GCIB processing apparatus for directing the gas cluster ion beam onto the major surface plane of a substrate at the desired angle.

FIG. 11 is a schematic graphical illustration of a view of a method as described herein of processing a semiconductor substrate with a recess extending into the semiconductor substrate.

FIG. 12 is a schematic graphical illustration of a view of a method as described herein of processing a semiconductor substrate with recesses extending into the semiconductor substrate.

FIG. 13 is a schematic graphical perspective illustration of a view of a semiconductor substrate with recesses and extending into the semiconductor substrate being treated by gas cluster ion beam with rotation of the semiconductor substrate.

FIG. 14 is a schematic graphical perspective illustration of a view of a semiconductor substrate with a recess extending into the semiconductor substrate.

### DETAILED DESCRIPTION

The aspects of the present invention described below are not intended to be exhaustive or to limit the invention to the precise forms disclosed in the following detailed description. Rather a purpose of the aspects chosen and described is by way of illustration or example, so that the appreciation and understanding by others skilled in the art of the general principles and practices of the present invention can be facilitated.

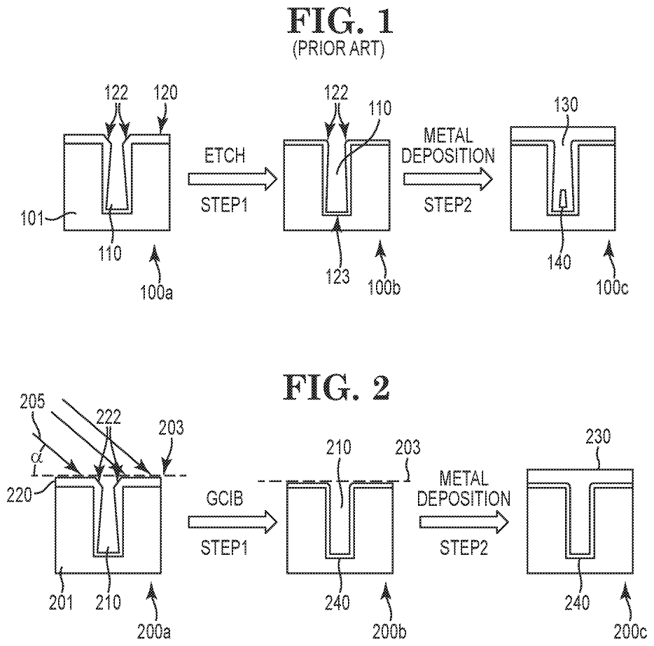

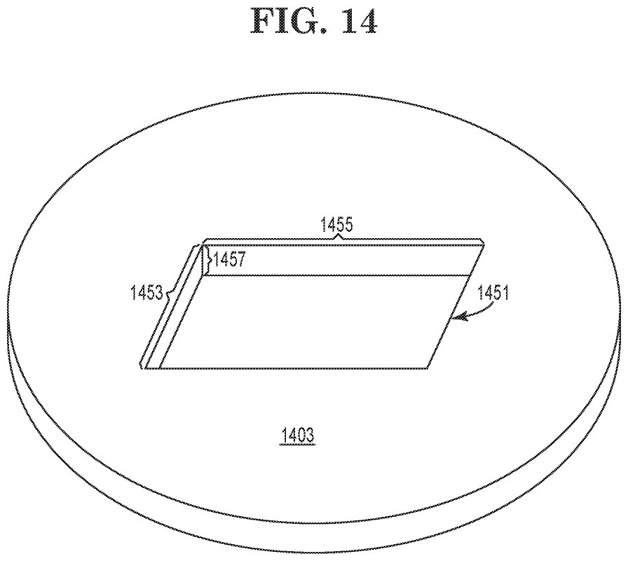

Turning now to the Figures, FIG. 1 is a schematic graphical illustration of a view of a prior art method of preparing a metal interconnect via structure 100c comprising a semiconductor substrate 101 having a recess 110 extending into a semiconductor substrate 101, the recess being lined with a metal-containing material 120 and being filled with an interconnect metal 130. FIG. 14 is a schematic graphical perspective illustration showing orientation of recess 1451 in substrate 1403. Recess 1451 as shown has a rectangular shape in the plane of the major surface of substrate 1403, but optionally could have any configuration, such as square, circular, ovoid, etc. Recess 1451 has a width 1453 and a length 1455 in the plane of the major surface of substrate 1403. Recess 1451 extends into substrate 1403 to a depth 1457.

As noted above, at least one recess has a recess width in the narrowest dimension of not more than 50 nm. In an embodiment, the at least one recess has a recess width in the narrowest dimension of not more than 40 nm. In an embodiment, the at least one recess has a recess width in the narrowest dimension of not more than 35 nm. In an embodiment, the at least one recess has a recess width in the narrowest dimension of not more than 30 nm. In an embodiment, the at least one recess has a recess width in the narrowest dimension of not more than 25 nm. In an embodiment, the at least one recess has a recess width in the narrowest dimension of not more than 20 nm.

In an embodiment, the at least one recess has a recess depth in the narrowest dimension of not more than 50 nm. In an embodiment, the at least one recess has a recess depth in the narrowest dimension of not more than 40 nm. In an embodiment, the at least one recess has a recess depth in the narrowest dimension of not more than 35 nm. In an embodiment, the at least one recess has a recess depth in the narrowest dimension of not more than 30 nm. In an embodiment, the at least one recess has a recess depth in the narrowest dimension of not more than 25 nm. In an embodiment, the at least one recess has a recess depth in the narrowest dimension of not more than 20 nm.

As noted above, since Ru (or other metals) may need a liner material to improve adhesion on ILDs or a seed material to improve coating of the interconnect metal in the feature, the metal-containing material 120 preferably is deposited as a liner in such a way as to form a continuous layer on the sidewalls of the trenches and vias. Examples of methods of depositing such metal-containing thin films are Physical Vapor Deposition (PVD), Ionized Physical Vapor Deposition (iPVD), and Chemical Vapor Deposition (CVD). The methods of depositing the interconnect metal further may require a metal seed layer to be deposited before the subsequent filling of the trenches and vias.

Typical metal-containing materials are metals or metal alloys. In an embodiment the metal-containing material is selected from a metal oxide or metal nitride and combinations thereof. In an embodiment the metal-containing material is selected from Ru, W, Mo, and Nb, TiN, Ta, TaN, Nb, and NbN and combinations thereof.

In the method, intermediate structure 100a is a semiconductor substrate 101 having a recess 110 extending into a semiconductor substrate 101, the recess being lined with a metal-containing material 120. The metal-containing material 120 has a material overhang 122 causing a restriction (or “necking in” or “pinch off”) of the recess that when present may interfere with filling of the recess 110 with an interconnect metal 130. In Step 1, intermediate structure 100a is treated by etching with dry etch or thermal etch in an attempt to reduce the amount of over-hang of metal-containing material in preparation of intermediate structure 100b. However, as shown in intermediate structure 100b such etching procedures has been found to fail to remove all of the material overhang 122 and additionally results in removal of a portion of the metal-containing material at the bottom of the recess 123. Attempts to avoid removal of metal-containing material from the bottom of the recess by reducing the aggressiveness of the etch step have been found to insufficiently remove the overhang of material.

Recess 110 of intermediate structure 100b is filled with interconnect metal 130 by metal deposition in Step 2. However, due to the presence of material overhang 122, void 140 is produced in the resulting structure 100c, where the interconnect metal 130 is unable to fill the recess 110. The uneven distribution of metal-containing material 120 (including optional metal-containing seed material (not shown) may also result in poor sidewall coverage, especially near the bottom corners of recess 110. The poor sidewall coverage may alternatively result in too thin of a layer of metal-containing material 120 to prevent metal diffusion and/or too thin of a metal seed layer to allow subsequent metal growth at the bottom of recess 110. This thinner material at the bottom may cause the structures to have performance issues, such as substantially higher intrinsic resistivities.

FIG. 2 is a schematic graphical illustration of a view of a method of preparing a metal interconnect via product structure 200c comprising a semiconductor substrate 201 having a major surface plane 203 and a recess 210 extending into a semiconductor substrate 201, the recess being lined with a metal-containing material 220 and being filled with interconnect metal 230.

In the method, intermediate structure 200a is a semiconductor substrate 201 having a recess 210 extending into a semiconductor substrate 201, the recess being lined with a metal-containing material 220. The metal-containing material 220 has a material overhang 222 causing a restriction (or “necking in” or “pinch off”) of the recess that when present is known to interfere with filling of the recess 210 with an interconnect metal 230. Intermediate structure 200a is treated in Step 1 by directing a gas cluster ion beam (“GCIB”) 205 at the major surface plane 203 with a first irradiation angle α between the gas cluster ion beam and the major surface plane 203 of from 5° to 85° to remove at least a portion of the undesired metal-containing material. In an embodiment, the irradiation angle α between the gas cluster ion beam and the major surface plane 203 of from 5° to 60°. In an embodiment, the irradiation angle α between the gas cluster ion beam and the major surface plane 203 of from 30° to 60°. In an embodiment, the irradiation angle α between the gas cluster ion beam and the major surface plane 203 of from 5° to 45°. In an embodiment, the irradiation angle α between the gas cluster ion beam and the major surface plane 203 of from 30° to 45°. Because the GCIB 205 strikes intermediate structure 200a at an incident angle, the only materials that are etched/modified in Step 1 are the metal-containing material on the top surface and upper regions of the sidewall of the recess 210. Thus, the GCIB is highly effective in removing the material overhang 222, while having limited impact on the integrity of the metal-containing material located at the bottom 240 of recess 210 as shown in intermediate structure 200b.

In Step 2, the recess 210 of intermediate structure 200b is optionally dry etched with halogen or other gases as desired for further removal of a portion of metal-containing material 240. The thus prepared recess 210 is then filled with interconnect metal 230 by metal deposition to provide product structure 200c. Due to the absence of material overhang 222 in intermediate structure 200b, no interconnect metal void is produced in product structure 200c. Excellent uniformity of distribution of metal-containing material 240 (including optional metal seed material (not shown) may be observed.

Various configurations of the gas cluster ion beam as discussed with respect to FIG. 2 will be further described below.

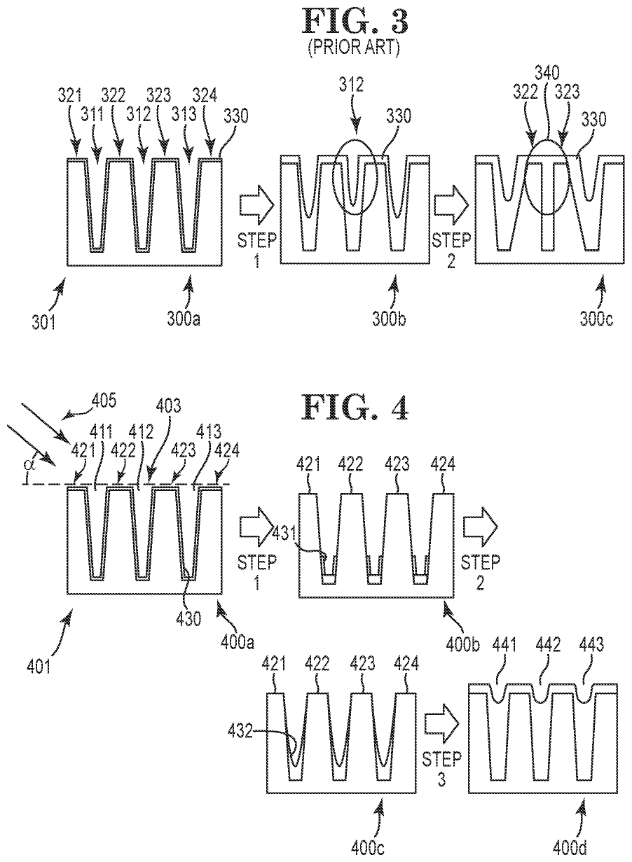

FIG. 3 is a schematic graphical illustration of a view of a prior art method of processing a semiconductor substrate 301 comprising a number of adjacent, very small features. In the method, intermediate structure 300a is a semiconductor substrate 301 having a plurality of recesses 311, 312, 313 extending into semiconductor substrate 301 to provide number of adjacent, very small features bounded by thin semiconductor walls 321, 322, 323, 324 having high aspect ratios. An initial layer of a pre-filled interconnect metal 330 is deposited to provide initial reinforcement of the thin semiconductor walls 321, 322, 323, 324. In Step 1, more interconnect metal is added to the plurality of recesses 311, 312, 313 by metal deposition. As can be seen in intermediate structure 300b the separate recesses inevitably fill at different rates. Thus, a middle recess 312 fills more quickly than adjacent recesses 311 and 313. The addition of yet more interconnect metal 330 by metal deposition in Step 2 imparts surface tension forces that lead to line bending as shown in structure 300c, whereby thin semiconductor walls 322 and 323 are drawn together, creating a seamless structure 340 in the feature pattern.

FIG. 4 is a schematic graphical illustration of a view of a method as described herein of processing a semiconductor substrate 401 having a major surface plane 403 comprising a number of adjacent, very small features having relatively high aspect ratios (i.e., the ratio of the height of the walls of the feature to the width of the base of the wall of the feature). In an embodiment, the aspect ratios are from 3:1 to 6:1. In an embodiment, the aspect ratios are from 3.5:1 to 5:1. In the method, intermediate structure 400a is a semiconductor substrate 401 having a plurality of recesses 411, 412, 413 extending into a semiconductor substrate 401 to provide number of adjacent, very small features bounded by thin semiconductor walls 421, 422, 423, 424 having relatively high aspect ratios. An initial layer of an interconnect metal or metal-containing material 430 is deposited to provide initial reinforcement of the thin semiconductor walls 421, 422, 423, 424.

Intermediate structure 400a is treated in Step 1 by directing a gas cluster ion beam (“GCIB”) 405 at the major surface plane 403 with a first irradiation angle α between the gas cluster ion beam and the major surface plane 403 of from 5° to 85° to remove at least a portion of the undesired metal-containing material. Because the GCIB 405 strikes intermediate structure 400a at an incident angle, the only materials that are etched/modified in Step 1 are the metal-containing materials on the top surface and upper regions of the sidewall of the recesses 411, 412, 413, leaving behind a reinforcing portion of interconnect metal 431 at the bottom and lower sides of the recesses as shown in intermediate structure 400b.

In Step 2, more interconnect metal is added to the plurality of recesses 411, 412, 413. As may be seen in intermediate structure 400c, the already solidified interconnect metal 431 at the bottom and lower sides of the recesses reinforces the thin semiconductor walls 421, 422, 423, 424 to counter surface tension forces, thereby preventing line bending. The thus added interconnect metal provides a further a reinforcing portion of interconnect metal 432 adjacent to the reinforcing portion of interconnect metal 431 at the bottom and lower sides of the recesses.

In Step 3, yet more interconnect metal is added to the plurality of recesses 411, 412, 413 to provide product structure 400c having a number of adjacent, very small features 441, 442, 443 with no voids in the feature pattern.

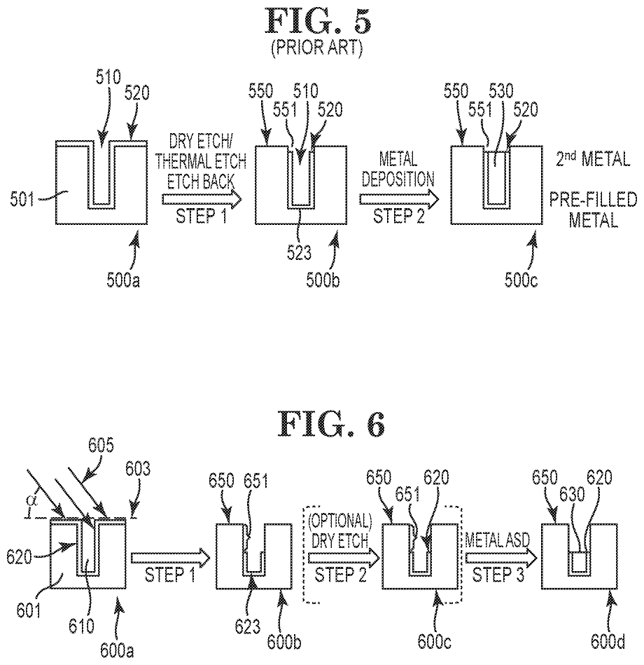

FIG. 5 is a schematic graphical illustration of a view of a prior art method of processing a recess extending into a semiconductor substrate comprising metal-containing material by conventional dry etch or thermal etch techniques. In the method, intermediate structure 500a is a semiconductor substrate 501 having a recess 510 extending into a semiconductor substrate 501, the recess being lined with a metal-containing material 520. In Step 1, intermediate structure 500a is treated by etching with dry etch or thermal etch to remove the portion of metal-containing material 520 on the top surface 550 of semiconductor substrate 501 and the upper portion of the side of recess 510 to facilitate placement of interconnect metal 530 at only the lower portion of recess 510. However, such etching procedures has been found to be difficult to control. As shown in the resulting intermediate structure 500b, only a small portion of metal-containing material 520 is removed from the upper portion of the side of recess 510, and additionally an undesired amount a portion of the pre-filled material at the bottom of the recess 523 is removed. Attempts to avoid removal of pre-filled material from the bottom of the recess by reducing the aggressiveness of the etch step have been found to exasperate problems in removing the desired portion of metal-containing material 520 from the upper portion of the side of recess 510. Recess 510 of intermediate structure 500b is filled with interconnect metal 530 by metal deposition in Step 2, which tends to adhere to the entire available surfaces coated with pre-filled material 520. Since, as shown in intermediate structure 500b, only a small portion of metal-containing material 520 is removed from the upper portion 551 of the side of recess 510 by conventional etch techniques, recess 510 is filled undesirably almost to top surface 550, which complicates subsequent fabrication steps.

FIG. 6 is a schematic graphical illustration of a view of a method as described herein of processing a recess extending into a semiconductor substrate comprising a metal-containing material. In the method, intermediate structure 600a is a semiconductor substrate 601 having a recess 610 extending into a semiconductor substrate 601, the recess being lined with a metal-containing material 620. In Step 1, intermediate structure 600a is treated by directing a gas cluster ion beam (“GCIB”) 605 at the major surface plane 603 with a first irradiation angle α between the gas cluster ion beam and the major surface plane 603 of from 5° to 85° to remove at least a portion of the undesired metal-containing material. Because the GCIB 605 strikes intermediate structure 600a at an incident angle, the only materials that are etched/modified in Step 2 are the metal-containing material on the top surface 650 and upper regions 651 of the sidewall of the recess 610, as illustrated in intermediate structure 600b. Thus, the GCIB is highly effective in removing the upper portion of metal-containing material 620 from the side of recess 610 to facilitate placement of interconnect metal 630 at only the lower portion of recess 610. Moreover, use of GCIB directed at an angle relative to the major surface plane 603 advantageously results in limited impact on the integrity of the metal-containing material located at the bottom 623 of recess 610.

In Step 2, the recess 610 of intermediate structure 600b is optionally dry etched, for example with halogen, as desired for further removal of metal-containing material. Recess 610 is then filled with interconnect metal 630 by metal deposition in Step 3 to provide product structure 600d. Due to removal of the correct amount of metal-containing material 620 in Step 1 (and optional Step 2), the desired amount of interconnect metal 630 is deposited only at the lower portion of recess 610.

FIG. 7 is a schematic graphical illustration of a view of a prior art method of processing a recess extending into a semiconductor substrate comprising a metal-containing material having metal nuclei by conventional dry etch or thermal etch techniques. In the method, intermediate structure 700a is a semiconductor substrate 701 having a recess 710 extending into a semiconductor substrate 701, the recess having a portion of metal-containing material 726 deposited at the lower portion of recess 710. During preparation of the intermediate structure 700a, undesired metal nuclei 728 have been formed and deposited on the top surface 750 of semiconductor substrate 701 and the upper side walls 711 of recess 710. The presence of such metal nuclei 728 is problematic, because if the nuclei are not removed, a metal film of the interconnect metal 730 will grow around the nuclei and eventually form a continuous film coating the top surface 750 of semiconductor substrate 701 and the upper side walls 711 of recess 710. In the illustrated prior art technique, intermediate structure 700a is treated in Step 1, by etching with dry etch or thermal etch to remove the undesired metal nuclei 728 the top surface 750 of semiconductor substrate 701 and the upper side walls 711 of recess 710. However, it has been found that this etch step also removes some of the metal-containing material 726 deposited at the lower portion of recess 710, providing a layer of metal-containing material 726 having an undesirably reduced thickness. Additionally, if the etch step is aggressive, the etch may remove a portion of the top surface 750 of semiconductor substrate 701.

When the recess 710 of intermediate structure 700b is filled with interconnect metal 730 by metal deposition in Step 2, an excessive amount of interconnect metal 730 is present. However, the interconnect metal 730 could not reach the required height level since the thickness of pre-filled metal 726 has been reduced during the Step 1 for nuclei removal.

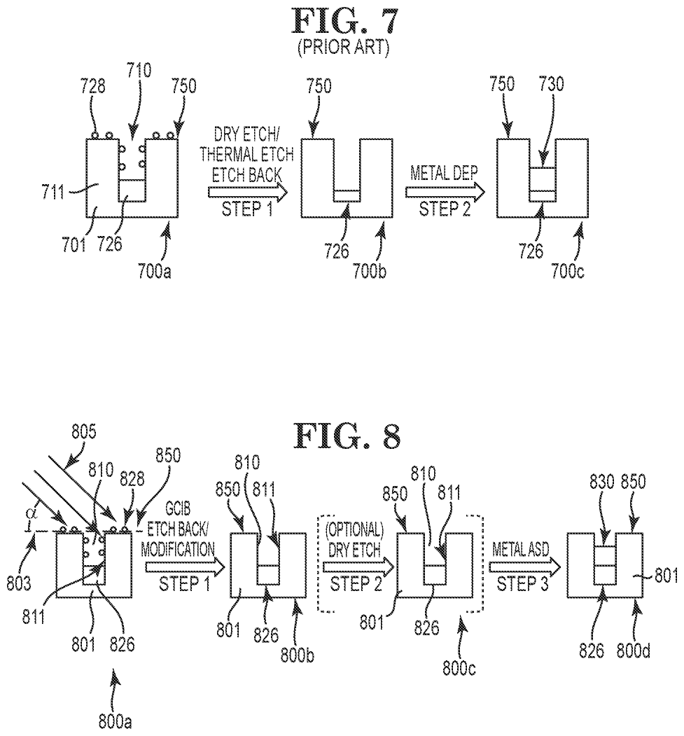

FIG. 8 is a schematic graphical illustration of a view of a method as described herein of processing a recess extending into a semiconductor substrate comprising a metal pre-filled material having metal nuclei. In the method, intermediate structure 800a is a semiconductor substrate 801 having a recess 810 extending into a semiconductor substrate 801, the recess having metal-containing material 826 deposited at the lower portion of recess 810. During preparation of the intermediate structure 800a, undesired metal nuclei 828 have been formed and deposited on the top surface 850 of semiconductor substrate 801 and the upper side walls 811 of recess 810.

In Step 1, intermediate structure 800a is treated by directing a gas cluster ion beam (“GCIB”) 805 at the major surface plane 803 with a first irradiation angle α between the gas cluster ion beam and the major surface plane 803 of from 5° to 85° to remove at least a portion of the undesired metal-containing material. Because the GCIB 805 strikes intermediate structure 800a at an incident angle, the only materials that are etched/modified in Step 1 are the undesired metal nuclei 828 on the top surface 850 of semiconductor substrate 801 and the upper side walls 811 of recess 810. Thus, as shown in intermediate structure 800b, the undesired metal nuclei 828 are removed from the top surface 850 of semiconductor substrate 801 and the upper side walls 811 of recess 810 by GCIB 805. Moreover, use of GCIB directed at an angle relative to the major surface plane 803 advantageously results in limited impact on the integrity of the pre-filled material located at the bottom of recess 810. The use of GCIB directed at an angle as described herein can remove the metal nuclei on the top surface and the sidewall and minimize the reduction of pre-filled material located at the bottom of recess 810. By doing this, the pre-filled metal height can be maintained. Additionally, the use of GCIB directed at an angle as described herein facilitates accurate removal of undesired metal nuclei 828, avoiding the need to apply excessive treatment that may remove top surface 850 of semiconductor substrate 801 that would undesirably reduce the size of the feature being fabricated.

In optional Step 2, the recess 810 of intermediate structure 800b may be dry etched or thermal etched (for example with halogen) as desired for further removal of any pre-filled material and/or undesired metal nuclei 828 that may be present after Step 1 to provide intermediate structure 800c.

After removal of the undesired metal nuclei 828, interconnect metal 830 is deposited in Step 3 on top of metal-containing material 826 deposited at the lower portion of recess 810 with targeted total height level of pre-filled metal and interconnect metal as shown in structure 800d.

Gas cluster ion beam devices (“GCIB devices”) are known in the art and are described, for example, in U.S. Pat. Nos. 7,115,511; 7,550,748; 9,209,033; 11,450,506; and US Patent Application Publication Number 2014/0299465, the disclosures of which are incorporated by reference herein for purposes of describing components of GCIB devices, configurations of components of GCIB devices and materials used in operation of components of GCIB devices.

In general, a GCIB device may be described as follows: a vacuum vessel is divided into three communicating chambers, a source chamber, an ionization/acceleration chamber, and a processing chamber. The three chambers are evacuated to suitable operating pressures by vacuum pumping systems. A condensable source gas (for example argon or N2) stored in a gas storage cylinder is admitted under pressure through a gas metering valve and gas feed tube into stagnation chamber and is ejected into the substantially lower pressure vacuum through a properly shaped nozzle, providing a supersonic gas jet. Cooling, which results from the expansion in the jet, causes a portion of the gas jet to condense into clusters, each consisting of from several to several thousand weakly bound atoms or molecules. A gas skimmer aperture partially separates the gas molecules that have not condensed into a cluster jet from the cluster jet so as to minimize pressure in the downstream regions where such higher pressures would be detrimental (e.g., ionizer, high voltage electrodes, and process chamber). Suitable condensable source gases include, but are not necessarily limited to argon, nitrogen, carbon dioxide, oxygen, and other gases.

After the supersonic gas jet containing gas clusters has been formed, the clusters are ionized in an ionizer. The ionizer is typically an electron impact ionizer that produces thermoelectrons from one or more incandescent filaments and accelerates and directs the electrons causing them to collide with the gas clusters in the gas jet, where the jet passes through the ionizer. The electron impact ejects electrons from the clusters, causing a portion the clusters to become positively ionized. A set of suitably biased high voltage electrodes extracts the cluster ions from the ionizer, forming a beam, then accelerates them to a desired energy (typically from 1 keV to several tens of keV) and focuses them to form a GCIB. Filament power supply provides voltage V_{F} to heat the ionizer filament. Anode power supply provides voltage V_{A} to accelerate thermoelectrons emitted from filament to cause them to irradiate the cluster containing gas jet to produce ions. Extraction power supply provides voltage V_{E} to bias a high voltage electrode to extract ions from the ionizing region of ionizer and to form a GCIB. Accelerator power supply provides voltage V_{ACC} to bias a high voltage electrode with respect to the ionizer so as to result in a total GCIB acceleration energy equal to V_{ACC} electron volts (eV). One or more lens power supplies may be provided to bias high voltage electrodes with potentials to focus the GCIB.

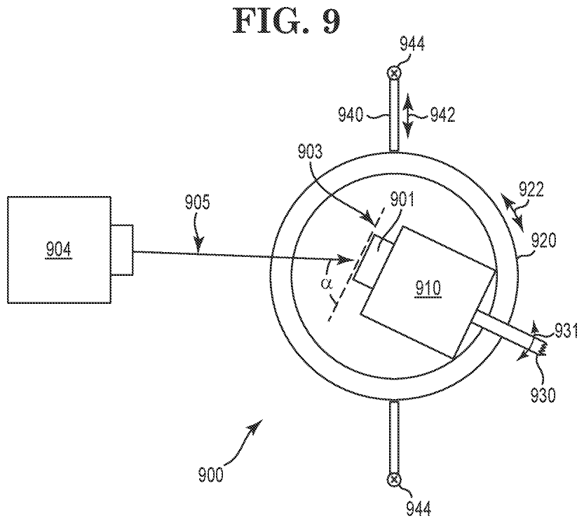

FIG. 9 is a schematic graphical illustration of a gas cluster ion beam processing apparatus 900 for directing the gas cluster ion beam onto the major surface plane of a substrate at the desired angle. A semiconductor substrate 901 having a major surface plane 903 is treated by directing a gas cluster ion beam 905 generated by GCIB device 904 at the major surface plane 903 with a first irradiation angle α between the gas cluster ion beam 905 and the major surface plane 203 of from 5° to 85° to remove at least a portion of the undesired metal-containing material. Substrate 901 is held by workpiece holder 910 to maintain the desired irradiation angle for treatment. Workpiece holder 910 is attached to angle setting mechanism 920, which can be rotated as indicated at rotation direction 922 to adjust the irradiation angle as desired to expose the substrate 901 to the gas cluster ion beam 905 from a plurality of angles.

Workpiece holder 910 may additionally be provided with turntable axle 930 that is perpendicular to the major surface plane 903. By rotating turntable axle 930 in rotation direction 931, the substrate is likewise rotated in the plane of major surface plane 903 to expose the substrate 901 to the gas cluster ion beam 905 from a plurality of directions relative to a given point on the substrate 901 without changing first irradiation angle α between the gas cluster ion beam 905 and the major surface plane 903. In an embodiment, workpiece holder 910 (and therefore substrate 901) is rotated stepwise to expose the substrate 901 to the gas cluster ion beam 905 from a plurality of directions relative to a given point on an edge of the substrate 901. In an embodiment, workpiece holder 910 (and therefore substrate 901) is rotated continuously to expose the substrate 901 to the gas cluster ion beam 905 from all directions (i.e., a full 360°) relative to a given point on an edge of the substrate 901.

Workpiece holder 910 and angle setting mechanism 920 may additionally or alternatively be provided with Y-scan actuator 940 that provides linear motion of the workpiece holder 910 in the direction of Y-scan motion 942, X-scan actuator 944 that provides linear motion of the workpiece holder 910 in the direction of X-scan motion (into and out of the plane of the drawing sheet). In an embodiment, the substrate is moved in an X and/or Y direction relative to the gas cluster ion beam to expose a plurality of zones of the substrate to the gas cluster ion beam. In an embodiment, the movement in the X and/or Y direction is a continuous scan movement relative to the gas cluster ion beam.

Alternatively, rather than moving the workpiece holder 910 to treat a plurality of zones of the substrate, the GCIB generator may in an embodiment be moved in the X and/or Y direction relative to the substrate to expose a plurality of zones of the substrate to the gas cluster ion beam.

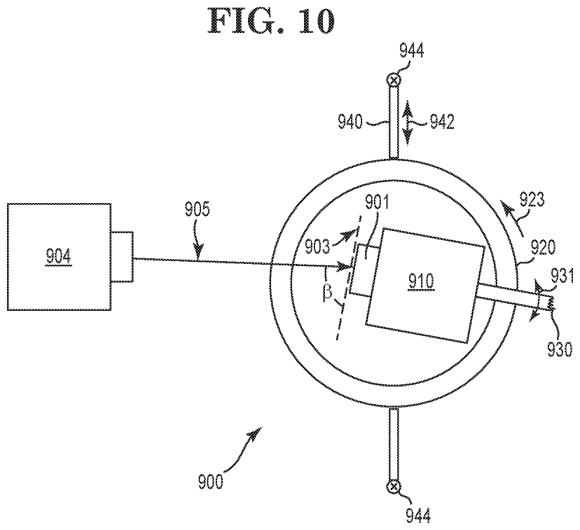

FIG. 10 is a schematic graphical illustration of a gas cluster ion beam processing apparatus 900 as shown in FIG. 9, wherein angle setting mechanism 920 has been rotated as indicated at rotation direction 923 to adjust the irradiation angle from first irradiation angle α to second irradiation angle β. In an embodiment, the angle setting mechanism 920 is rotated stepwise to expose the substrate 901 to a plurality of irradiation angles ranging from the first irradiation angle α to the second irradiation angle. It has been found that change of the irradiation angle can be instrumental in modifying the depth of sidewall etch in the method of processing a recess extending into a semiconductor substrate.

In an embodiment, the angle setting mechanism 920 is rotated continuously to expose the substrate 901 to all irradiation angles ranging from the first irradiation angle α to the second irradiation angle. It has been found that change of the irradiation angle by rotation of the angle setting mechanism can be instrumental to provide continuous control in modifying the depth of sidewall etch in the method of processing a recess extending into a semiconductor substrate.

Alternatively, rather than rotating the angle setting mechanism to adjust the irradiation angle between the gas cluster ion beam and the major surface plane, the GCIB generator may in an embodiment be moved relative to the substrate to adjust the irradiation angle between the gas cluster ion beam and the major surface plane.

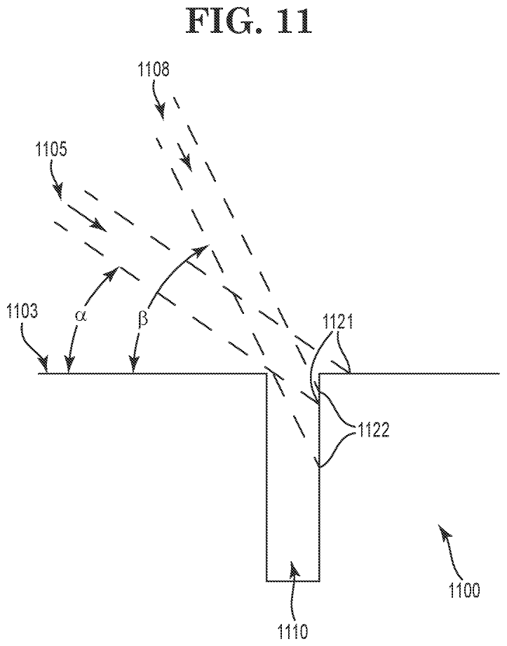

FIG. 11 is a schematic graphical illustration of a view of a method as described herein of processing a semiconductor substrate 1100 with a recess 1110 extending into the semiconductor substrate. A gas cluster ion beam (“GCIB”) 1105 is directed at the major surface plane 1103 with a first irradiation angle α between the GCIB 1105 and the major surface plane 1103. GCIB 1105 contacts semiconductor substrate 1100 in an impact zone 1121. In the method, a GCIB 1108 is directed at the major surface plane 1103 with a second irradiation angle β between the gas cluster ion beam 1108 and the major surface plane 1103. GCIB 1108 contacts semiconductor substrate 1100 in an impact zone 1122. Because of the change in orientation of the GCIB from first irradiation angle α to second irradiation angle β, the different areas on the semiconductor substrate 1100 are selectively treated.

In an embodiment, the GCIB 1108 is generated by a different GCIB device than generated the GCIB 1105. In an embodiment, the GCIB 1108 is generated by the same GCIB device that generated the GCIB 1105, the irradiation angle of the beam being adjusted from the first irradiation angle α to the second irradiation angle β by rotating the angle setting mechanism to adjust the irradiation angle between the gas cluster ion beam and the major surface plane. In an embodiment, the irradiation angle of the beam is adjusted from the first irradiation angle α to the second irradiation angle β by moving the GCIB generator itself relative to the substrate.

In an embodiment, the GCIB does not contact the substrate during the step of adjusting the irradiation angle from the first irradiation angle α to the second irradiation angle β. For example, the GCIB device may be turned off, or the beam may be interrupted by a shutter to block contact of the GCIB with the substrate during movement of the substrate or the GCIB device.

In an embodiment, the GCIB contacts the substrate during the step of adjusting the irradiation angle from the first irradiation angle α to the second irradiation angle β, providing a continuous sweeping exposure of the GCIB to the area on the semiconductor substrate to be selectively treated.

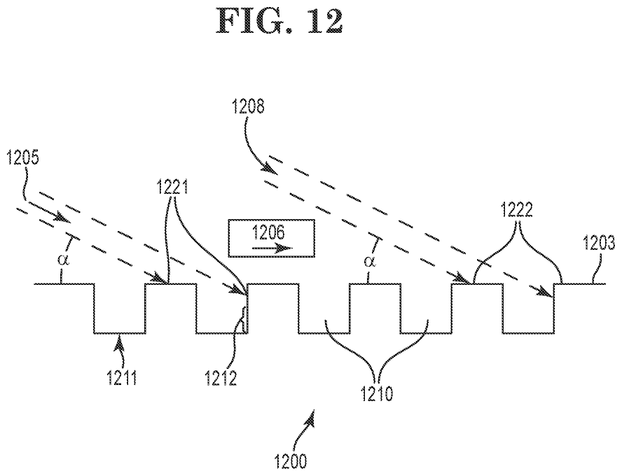

FIG. 12 is a schematic graphical illustration of a view of a method as described herein of processing a semiconductor substrate 1200 with recesses 1210 extending into the semiconductor substrate. A gas cluster ion beam (“GCIB”) 1205 is directed at the major surface plane 1203 with a first irradiation angle α between the GCIB 1205 and the major surface plane 1203. GCIB 1205 contacts semiconductor substrate 1200 in an impact zone 1221. In the method, GCIB 1205 is shifted in direction 1206 to GCIB location 1208, still directed at the major surface plane 1203 with a first irradiation angle α between the gas cluster ion beam 1208 and the major surface plane 1203. The beam at GCIB location 1108 contacts semiconductor substrate 1200 in an impact zone 1222. Because of the low irradiation angle α, the GCIB does not impact the bottom 1211 or lower side portions 1212 of recesses 1210.

In an embodiment, the GCIB 1205 is shifted in direction 1206 to GCIB location 1208 by moving the substrate in an X and/or Y direction relative to the gas cluster ion beam to expose a portion of or the entire major surface plane of the substrate to the gas cluster ion beam. It should be noted that movement of the semiconductor substrate 1200 in an X and/or Y direction without rotation does not change the irradiation angle of the gas cluster ion beam relative to the major surface plane 1203 of the substrate, but changes the location of the impact zone.

In an embodiment, the movement in the X and/or Y direction is a continuous scan movement.

In an embodiment, the GCIB does not contact the substrate during the step of shifting the GCIB 1205 in direction 1206 to GCIB location 1208. For example, the GCIB device may be turned off, or the beam may be interrupted by a shutter to block contact of the GCIB with the substrate during movement of the substrate or the GCIB device.

In an embodiment, the GCIB contacts the substrate during the step of shifting the GCIB 1205 in direction 1206 to GCIB location 1208, providing a continuous scanning treatment of the area on the semiconductor substrate to be selectively treated.

In an embodiment, the irradiation angle of the GCIB is adjusted from the first irradiation angle α to a second irradiation angle β between the gas cluster ion beam and the major surface plane of from 5° to 85°, wherein the second irradiation angle β (not shown) is different from the first irradiation angle α), while by moving the substrate in an X and/or Y direction relative to the gas cluster ion beam to expose a portion of or the entire major surface plane of the substrate to the gas cluster ion beam. In an embodiment, the second irradiation angle β between the gas cluster ion beam and the major surface plane is from 5° to 60°. In an embodiment, the second irradiation angle β between the gas cluster ion beam and the major surface plane is from 30° to 60°. The movement of the substrate itself in an X and/or Y direction relative to the gas cluster ion beam in combination with changing the irradiation angle advantageously affords the ability to carry out highly selective surface treatments at different portions of the semiconductor substrate 1200 in a unique and efficient manner. It has been found that moving the substrate in an X and/or Y direction relative to the gas cluster ion beam allows GCIB to provide a different level etch and/or application of the GCIB to a different area of the substrate, facilitating a fine tuning of etch in different areas of the substrate.

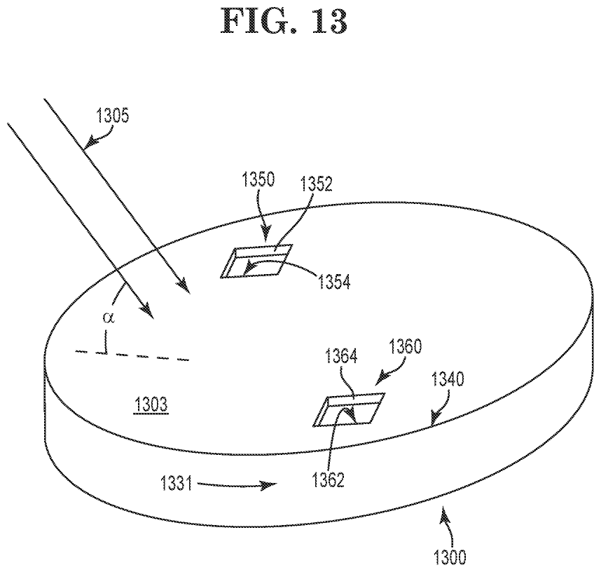

FIG. 13 is a schematic graphical perspective illustration of a view of a semiconductor substrate 1300 with recesses 1350 and 1360 extending into the semiconductor substrate being treated by gas cluster ion beam (“GCIB”) with rotation of the semiconductor substrate 1300. Recess 1350 has an outside wall 1352 proximal to substrate edge 1340, and an inside wall 1354 distal from substrate edge 1340. Likewise, recess 1360 has an outside wall 1362 proximal to substrate edge 1340, and an inside wall 1364 distal from substrate edge 1340. GCIB 1305 is directed at the major surface plane 1303 with a first irradiation angle α between the GCIB 1305 and the major surface plane 1303. Semiconductor substrate 1300 is mounted on a workpiece holder provided with turntable axle that is perpendicular to the major surface plane 1303, such as is illustrated in FIG. 9. Semiconductor substrate 1300 is rotated in the plane of major surface plane 1303 in direction 1331 to expose the substrate 1300 to the gas cluster ion beam 1305 from a plurality of directions relative to a given point on the substrate 1300 without changing first irradiation angle α between the gas cluster ion beam 1305 and the major surface plane 1303. Due to the orientation of semiconductor substrate 1300 to GCIB 1305 as shown in FIG. 13, GCIB contacts inside wall 1354 of recess 1350, but does not contact outside wall 1352. Likewise, GCIB contacts outside wall 1362 of recess 1360, but does not contact inside wall 1364.

Upon rotation of semiconductor substrate 1300 a half turn (i.e. 180 degrees) in the plane of major surface plane 1303 in direction 1331, the previously shaded portions of the recesses are exposed to GCIB 1305. Thus, after rotation GCIB contacts outside wall 1352 of recess 1350, but does not contact inside wall 1354; and GCIB contacts inside wall 1364 of recess 1360, but does not contact outside wall 1362.

In an embodiment, semiconductor substrate 1300 can be treated by stepwise incremental rotation, e.g. in 30 degree, 45 degree, 60 degree, 90 degree increments, with or without GCIB interruption between rotation steps. In an embodiment, semiconductor substrate 1300 can be treated with continuous rotation during GCIB treatment.

In an embodiment, the substrate can be moved in an X and/or Y direction relative to the gas cluster ion beam to treat a plurality of zones of the substrate while rotating semiconductor substrate 1300 in the plane of major surface plane 1303 in direction 1331 to expose the substrate 1300 to the gas cluster ion beam 1305 from a plurality of directions relative to a given point on the substrate 1300. In an alternative embodiment, the GCIB generator that generates a gas cluster ion beam can be moved in the X and/or Y direction relative to the substrate to treat a plurality of zones of the substrate while rotating semiconductor substrate 1300 in the plane of major surface plane 1303 in direction 1331 to expose the substrate 1300 to the gas cluster ion beam 1305 from a plurality of directions relative to a given point on the substrate 1300.

The movement of the substrate itself in an X and/or Y direction relative to the gas cluster ion beam in combination with rotating semiconductor substrate in the plane of major surface plane advantageously affords the ability to carry out highly selective surface treatments at different portions of the semiconductor substrate in a unique and efficient manner.

In an embodiment, the irradiation angle is changed from first irradiation angle α to a second irradiation angle β between the gas cluster ion beam and the major surface plane of from 5° to 85°, wherein the second irradiation angle β is different from the first irradiation angle α, while rotating semiconductor substrate 1300 in the plane of major surface plane 1303 in direction 1331 to expose the substrate 1300 to the gas cluster ion beam 1305 from a plurality of directions relative to a given point on the substrate 1300.

The rotation of the substrate relative to the gas cluster ion beam in combination with changing the irradiation angle advantageously affords the ability to carry out highly selective surface treatments at different portions of the semiconductor substrate in a unique and efficient manner.

In an embodiment, the substrate can be moved in an X and/or Y direction relative to the gas cluster ion beam to treat a plurality of zones of the substrate while the irradiation angle is changed from first irradiation angle α to a second irradiation angle β between the gas cluster ion beam and the major surface plane of from 5° to 85°, wherein the second irradiation angle β is different from the first irradiation angle α, and also while rotating semiconductor substrate 1300 in the plane of major surface plane 1303 in direction 1331 to expose the substrate 1300 to the gas cluster ion beam 1305 from a plurality of directions relative to a given point on the substrate 1300.

In an alternative embodiment, the GCIB generator that generates a gas cluster ion beam can be moved in the X and/or Y direction relative to the substrate to treat a plurality of zones of the substrate while the irradiation angle is changed from first irradiation angle α to a second irradiation angle β between the gas cluster ion beam and the major surface plane of from 5° to 85°, wherein the second irradiation angle β is different from the first irradiation angle α, and also while rotating semiconductor substrate 1300 in the plane of major surface plane 1303 in direction 1331 to expose the substrate 1300 to the gas cluster ion beam 1305 from a plurality of directions relative to a given point on the substrate 1300.

The movement of the substrate itself in an X and/or Y direction relative to the gas cluster ion beam in combination with rotating semiconductor substrate in the plane of major surface plane and also while changing the irradiation angle from first irradiation angle α to a second irradiation angle β advantageously affords the ability to carry out highly selective surface treatments at different portions of the semiconductor substrate in a unique and efficient manner.

In an embodiment, the gas cluster ion beam used in the present method may comprise inert gases such as nitrogen, helium, neon, argon, krypton, and xenon.

In an embodiment, the gas cluster ion beam used in the present method may comprise a mixture of an inert gas and a reactive gas such as fluorine (F), SF₆, CF₄, Cl₂, BCl₃, O₂, NO, N₂O CO₂, NH₃, NF₃, SF₆, CF₄, CHF₃, or the like, or a mixture of several gases.

In an embodiment, the method comprises administering a plurality of gas cluster ion beam treatments at the substrate. In an embodiment, the method comprises administering a gas cluster ion beam comprising only inert gases. In an embodiment, the method comprises administering a gas cluster ion beam comprising only reactive gases. In an embodiment, the method comprises administering a gas cluster ion beam comprising only inert gases and in a separate step administering a gas cluster ion beam comprising only reactive gases. In an embodiment, the method comprises administering a first gas cluster ion beam comprising only inert gases and in a separate step administering a second gas cluster ion beam comprising reactive gases. In an embodiment, the method comprises administering a first gas cluster ion beam comprising reactive gases and in a separate step administering a second gas cluster ion beam comprising only inert gases.

In an embodiment, gas cluster ion beam (GCIB) is formed from a pressurized gas mixture containing at least one reactive gas. The at least one reactive gas may include a halogen element. The at least one reactive gas may include a halogen element and one or more elements selected from the group consisting of C, H, N, O and S. The at least one reactive gas may include a halogen element and one or more elements selected from the group consisting of Si and Ge.

For example, the reactive gas may include F₂, Cl₂, Br₂, NF₃, or SF₆. Additionally, for example, the at least one reactive gas may include a halide, such as HF, HCl, HBr, or HI.

In an embodiment, the reactive gas may include a halosilane or halogermane, such as a mono-substituted halosilane or halogermane (SiH₃F, GeH₃F, etc.), di-substituted halosilane or halogermane (SiH₂F₂, GeH₂F₂, etc.), tri-substituted halosilane or halogermane (SiHF₃, GeHF₃, etc.), or tetra-substituted halosilane or halogermane (SiF₄, GeF₄, SiCl₄, GeCl₄, SiBr₄, or GeBr₄). Furthermore, for example, the at least one reactive gas may include a halomethane, such as a mono-substituted halomethane (e.g., CH₃F, CH₃Cl, CH₃Br, CH₃I), a di-substituted halomethane (e.g., CH₂F₂, CH₂ClF, CH₂BrF, CH₂F₁, CH₂Cl₂, CH₂BrCl, CH₂Cl₁, CH₂Br₂, CH₂BrI, CH₂I₂), a tri-substituted halomethane (e.g., CHF₃, CHClF₂, CHBrF₂, CHF₂I, CHCl₂F, CHBrClF, CHClFI, CHBr₂F, CHBrFI, CHFI₂, CHCl₃, CHBrCl₂, CHCl₂I, CHBr₂Cl, CHBrClI, CHCl₂, CHBr₃, CHBr₂I, CHBrI₂, CHI₃), or a tetra-substituted halomethane (e.g., CF₄, CClF₃, CBrF₃, CF₃I, CCl₂F₂, CBrClF₂, CClF₂I, CBr₂F₂, CBrF₂I, CF₂I₂, CCl₃F, CBrCl₂F, CCl₂FI, CBr₂ClF, CBrClFI, CClFI₂, CBr₃F, CBr₂FI, CBrFI₂, CFI₃, CCl₄, CBrCl₃, CCl₃I, CBr₂Cl₂, CBrCl₂I, CCl₂I₂, CBr₃Cl, CBr₂ClI, CBrClI₂, CClI₃, CBr₄, CBr₃I, CBr₂I₂, CBrI₃, Cl₄).

In an embodiment, a dry etching process may be additionally carried out after treatment with the gas cluster ion beam as described. Examples of dry etch processes include using O₂ GCIB to oxidize Ru to form RuOₓ, and then using Cl₂ plasma to make RuOₓ to RuOₓCl_{y} which is volatile so that Ru is etched by O₂ GCIB+Cl₂ plasma.

An example of a stepwise process is as follows:
Step: 1. GCIB for etch/composition modification of pre-filled metal-containing material:
   GCIB with an inclined angle to etch pre-filled material on the top surface and over-hang on sidewall of substrate or modify the composition of pre-filled material.
Step 2. Dry etch for metal etch (optional):
   Halogen-based plasma to etch the pre-filled metal-containing material with modified composition on top surface and over-hang on sidewall of structures.

Examples of Materials used is stepwise process:
1. Ru->GCIB O₂->RuOₓ->Cl-based plasma->RuOₓCl_{y} (volatile)
2. Mo->GCIB O₂->MoOx->Cl-based or Br-based plasma->MoOClx, MoOBrx (volatile)
3. W->GCIB O₂->WOₓ->F-based plasma->WF₆ (volatile)

In an embodiment, a heat etching process may be additionally carried out after treatment with the gas cluster ion beam as described.

As used herein, the terms “about” or “approximately” mean within an acceptable range for the particular parameter specified as determined by one of ordinary skill in the art, which will depend in part on how the value is measured or determined, e.g., the limitations of the sample preparation and measurement system. Examples of such limitations include preparing the sample in a wet versus a dry environment, different instruments, variations in sample height, and differing requirements in signal-to-noise ratios. For example, “about” can mean greater or lesser than the value or range of values stated by 1/10 of the stated values, but is not intended to limit any value or range of values to only this broader definition. For instance, a concentration value of 30% means a concentration between 27% and 33%. Each value or range of values preceded by the term “about” is also intended to encompass the embodiment of the stated absolute value or range of values. Alternatively, particularly with respect to biological systems or processes, the term can mean within an order of magnitude, preferably within 5-fold, and more preferably within 2-fold, of a value.

Throughout this specification and claims, unless the context requires otherwise, the word “comprise”, and variations such as “comprises” and “comprising”, will be understood to imply the inclusion of a stated integer or step or group of integers or steps but not the exclusion of any other integer or step or group of integer or step. When used herein “consisting of” excludes any element, step, or ingredient not specified in the claim element. When used herein, “consisting essentially of” does not exclude materials or steps that do not materially affect the basic and novel characteristics of the claim. In the present disclosure of various embodiments, any of the terms “comprising”, “consisting essentially of” and “consisting of” used in the description of an embodiment may be replaced with either of the other two terms.

All patents, patent applications (including provisional applications), and publications cited herein are incorporated by reference as if individually incorporated for all purposes. Unless otherwise indicated, all parts and percentages are by weight and all molecular weights are weight average molecular weights. The foregoing detailed description has been given for clarity of understanding only. No unnecessary limitations are to be understood therefrom. The invention is not limited to the exact details shown and described, for variations obvious to one skilled in the art will be included within the invention defined by the claims.

What is claimed is:

1. A method of processing a recess extending into a semiconductor substrate and having undesired metal-containing material comprising:
providing a semiconductor substrate comprising a major surface plane and having a recess extending into the semiconductor substrate having undesired metal-containing material on the major surface plane and/or in the recess, wherein at least one recess has a recess width in the narrowest dimension of not more than 50 nm;
loading the semiconductor substrate on a substrate holder; and
directing a gas cluster ion beam at the major surface plane with a first irradiation angle α between the gas cluster ion beam and the major surface plane of from 5° to 85° to remove at least a portion of the undesired metal-containing material.

2. The method of claim 1, wherein the at least one recess has a recess width in the narrowest dimension of not more than 40 nm, or wherein the at least one recess has a recess width in the narrowest dimension of not more than 35 nm, or wherein the at least one recess has a recess width in the narrowest dimension of not more than 30 nm, or wherein the at least one recess has a recess width in the narrowest dimension of not more than 25 nm, or wherein the at least one recess has a recess width in the narrowest dimension of not more than 20 nm.

3. The method of claim 1, wherein the at least one recess has a recess depth in the narrowest dimension of not more than 50 nm, or wherein the at least one recess has a recess depth in the narrowest dimension of not more than 40 nm, or wherein the at least one recess has a recess depth in the narrowest dimension of not more than 35 nm, or wherein the at least one recess has a recess depth in the narrowest dimension of not more than 30 nm, or wherein the at least one recess has a recess depth in the narrowest dimension of not more than 25 nm, or wherein the at least one recess has a recess depth in the narrowest dimension of not more than 20 nm.

4. The method of claim 1, wherein the metal-containing material is a metal alloy.

5. The method of claim 1, wherein the metal-containing material is selected from a metal oxide or metal nitride and combinations thereof.

6. The method of claim 1, wherein the metal-containing material is selected from Ru, W, Mo, and Nb, TiN, Ta, TaN, Nb, and NbN and combinations thereof.

7. The method of claim 1, wherein the first irradiation angle α between the gas cluster ion beam and the major surface plane is selected from the range of from 5° to 60°, or wherein the first irradiation angle α between the gas cluster ion beam and the major surface plane is selected from the range of from 30° to 60°, or wherein the first irradiation angle α between the gas cluster ion beam and the major surface plane is selected from the range of from 5° to 45°, or wherein the first irradiation angle α between the gas cluster ion beam and the major surface plane is selected from the range of from 30° to 45°.

8. The method of claim 1, further comprising a step of adjusting the irradiation angle from first irradiation angle α to a second irradiation angle β between the gas cluster ion beam and the major surface plane of from 5° to 85°, wherein the second irradiation angle β is different from the first irradiation angle α.

9. The method of claim 8, wherein the gas cluster ion beam does not contact the semiconductor substrate during the step of adjusting the irradiation angle from the first irradiation angle α to the second irradiation angle β.

10. The method of claim 9, wherein the gas cluster ion beam contacts the semiconductor substrate continuously during the step of adjusting the irradiation angle from the first irradiation angle α to the second irradiation angle β.

11. The method of claim 9, wherein the first irradiation angle α is at least 5° away from the second irradiation angle β.

12. The method of claim 9, wherein the first irradiation angle α is from 5° to 45° and the second irradiation angle β is from 30° to 85°.

13. The method of claim 1, further comprising directing a second gas cluster ion beam at the major surface plane with a second irradiation angle β between the gas cluster ion beam and the major surface plane of from 5° to 85° to remove at least a portion of the undesired metal-containing material, wherein the second irradiation angle β is different from the first irradiation angle α.

14. The method of claim 1, further comprising a step of moving the semiconductor substrate in an X and/or Y direction relative to the gas cluster ion beam to treat a plurality of zones of the semiconductor substrate; or further comprising a step of moving a GCIB generator that generates a gas cluster ion beam in the X and/or Y direction relative to the substrate to expose a plurality of zones of the semiconductor substrate to the gas cluster ion beam.

15. The method of claim 14, wherein the gas cluster ion beam does not contact the semiconductor substrate during the step of moving the substrate or moving the GCIB generator.

16. The method of claim 14, wherein the gas cluster ion beam contacts the semiconductor substrate continuously during the step of moving the substrate or moving the GCIB generator.

17. The method of claim 8, further comprising a step of moving the semiconductor substrate in an X and/or Y direction relative to the gas cluster ion beam to treat a plurality of zones of the semiconductor substrate; or further comprising a step of moving a GCIB generator that generates a gas cluster ion beam in the X and/or Y direction relative to the semiconductor substrate to expose a plurality of zones of the semiconductor substrate to the gas cluster ion beam.

18. The method of claim 1, further comprising rotating the semiconductor substrate in the plane of major surface plane to expose the semiconductor substrate to the gas cluster ion beam from a plurality of directions relative to a given point on the semiconductor substrate.

19. The method of claim 18, wherein the semiconductor substrate is not exposed to the gas cluster ion beam during the step of rotating the semiconductor substrate.

20. The method of claim 18, wherein the semiconductor substrate is exposed to the gas cluster ion beam continuously during the step of rotating the semiconductor substrate.

21. The method of claim 18, further comprising a step of moving the semiconductor substrate in an X and/or Y direction relative to the gas cluster ion beam to expose a plurality of zones of the semiconductor substrate to the gas cluster ion beam; or further comprising a step of moving a GCIB generator that generates a gas cluster ion beam in the X and/or Y direction relative to the semiconductor substrate to expose a plurality of zones of the semiconductor substrate to the gas cluster ion beam.

22. The method of claim 18, further comprising a step of adjusting the irradiation angle from first irradiation angle α to a second irradiation angle β between the gas cluster ion beam and the major surface plane of from 5° to 85°, wherein the second irradiation angle β is different from the first irradiation angle α.

23. The method of claim 22, further comprising a step of moving the semiconductor substrate in an X and/or Y direction relative to the gas cluster ion beam to expose a plurality of zones of the semiconductor substrate to the gas cluster ion beam; or further comprising a step of moving a GCIB generator that generates a gas cluster ion beam in the X and/or Y direction relative to the semiconductor substrate to expose a plurality of zones of the semiconductor substrate to the gas cluster ion beam.

24. The method of method of claim 1, wherein the undesired metal-containing material is an overhang of metal-containing material.

25. The method of method of claim 1, wherein the undesired metal-containing material is metal-containing material on top surface and upper regions of sidewalls of adjacent, features bounded by semiconductor walls having aspect ratios of from 3:1 to 6:1.

26. The method of method of claim 1, wherein the undesired metal-containing material is metal nuclei on top surface and upper side walls of recesses in a semiconductor substrate.

27. The method of claim 1, comprising administering a gas cluster ion beam comprising only inert gases.

28. The method of claim 1, comprising administering a gas cluster ion beam comprising only inert gases and in a separate step administering a gas cluster ion beam comprising only reactive gases.
